(19) United States
(12) Patent Application Publication
(10) Pub. No.: US 2005/0219929 A1
(43) Pub. Date: Oct. 6, 2005

(54) Method and apparatus achieving memory and transmission overhead reductions in a content routing network

(76) Inventor: Julio C. Navas, Concord, CA (US)

Correspondence Address: GLENN PATENT GROUP, 3475 EDISON WAY, SUITE L, MENLO PARK, CA, 94025, US

(21) Appl. No.: 11/094,085

(22) Filed: Mar. 29, 2005

Related U.S. Application Data
(60) Provisional application No. 60/558,037, filed on Mar. 30, 2004.

(51) Int. Cl. G11C 11/34

(52) U.S. Cl. 365/212

(57) ABSTRACT

The invention comprises a method in a content routing network for reducing memory and control information transmission overhead, comprising the step of compressing a summary bit vector of a Bloom Filter used in the content routing network. The summary bit vector is compressed using a technique which allows for direct and in-place manipulation to individual bits in the vector and does not allow for direct and in-place manipulation to individual bits in the vector.

### CROSS REFERENCE TO RELATED APPLICATIONS

This application claims benefit of U.S. Provisional Patent Application Ser. No. 60/558,037, filed on Mar. 30, 2004 which application is incorporated herein in its entirety by this reference thereto.

### BACKGROUND OF THE INVENTION

1. Technical Field

The invention relates to computer networks. More particularly, the invention relates to a method and apparatus for achieving memory and transmission overhead reduction in a content routing network.

2. Discussion of the Prior Art

A trend in the information, communication, and automation industries is for increasingly distributed solutions. Recent examples of this trend include the proposal for networked sensors, and the suggestion that large groups of such data sources could form large distributed information systems, referred to as networks of data sources. In the article Next Century Challenges: Mobile Networking for Smart Dust (published in MobiComm 1999), authors Kahn et al. discuss an example of a distributed network of data sources in the form of a network of sensors.

The primary idea of a network of data sources is that individual data sources, or perhaps small groups of data sources, would be connected to computer networks using standard communications protocols, such as the Internet Protocol (IP). Other devices on the network would then be able to access the data provided by the data sources, either individually or in aggregate depending on the application. In the most ambitious proposals, wireless networks of data sources define their topologies dynamically as they are deployed, and continuously redefine their links and routing schemes to account for new and failing nodes and optimal power management. Rudimentary forms of networks of data sources are already being used in some industrial process control systems, and future applications for networks of data sources are widely predicted in many domains.

The research systems CAN [S. Ratnasamy, P. Francis, M. Handley, R. Karp, and S. Shenker. A scalable content-addressable network. In Proceedings of the ACM SIGCOMM 2001 Conference (SIGCOMM-01), volume 31:4 of Computer Communication Review, pages 161-172, August 2001.] and CHORD [I. Stoica, R. Morris, D. Karger, M. F. Kaashoek, and H. Balakrishnan. Chord: A scalable peer-to-peer lookup service for Internet applications. In Proceedings of the ACM SIGCOMM 2001 Conference (SIGCOMM-01), volume 31:4 of Computer Communication Review, pages 149-160, August 2001.] make use of distributed hash tables for inserting and retrieving data objects in the following manner: These systems use a hash calculation to determine a destination node. The hash function calculation uses the data object's identifier to calculate a point in an n×m space. This space is previously divided into regions and each region will be served by a storage node. Once a calculation is made and a point in n×m space is determined, the storage node that serves that region is chosen as the destination. A message is then sent to that storage node to insert or retrieve the data.

However, CAN and CHORD are not able to tell what information is already inside the storage nodes. All data in CAN or CHORD must first be put into the system and partitioned into regional groups before they can be accessed. In addition, CAN and CHORD only work with prepackaged data objects at the file level, and only with their identifiers, and can be used as file systems but not as databases. Finally, the network graph that is possible with CAN and CHORD is flat, i.e. it only supports one layer of hierarchy.

The research system PlanetP [“PlanetP: Using Gossiping to Build Content Addressable Peer-to-Peer Information Sharing Communities”. F. M. Cuenca-Acuna, C. Peery, R. P. Martin, and T. D. Nguyen. In Proceedings of the 12th International Symposium on High Performance Distributed Computing (HPDC), June 2003.] improves upon CAN and CHORD by describing the content of a storage node using a Bloom filter and associating keywords with documents inside the Bloom filter instead of just object identifiers. However, PlanetP still deals with objects at the file level, not down to the underlying data items.

The research system by Ledlie et al. [J. Ledlie, J. Taylor, L. Serban, M. Seltzer. Self-organization in peer-to-peer systems. In Pro-ceedings of the 10th European SIGOPS Workshop, September 2002.] adds grouping and hierarchy and introduces some hierarchy so that groups of nodes are governed by a leader, which is a more stable, long-lasting node that forms a peer-to-peer network using Bloom Filters in a manner similar to that described in PlanetP, except that the Bloom Filters cover objects held by the group. The group leader controls routing within a group and other group-specific issues. However, this system can effectively handle only two layers of hierarchy.

Byers, Considine, Mitzenmacher, and Rost [J. Byers, J. Considine, M. Mitzenmacher, and S. Rost. Informed content delivery over adaptive overlay networks. In Proc. of the ACM SIGCOMM 2002 Conference (SIGCOMM-02), vol. 32:4 of Computer Communication Review, pages 47-60, October 2002.] demonstrate using Bloom filters to control the parallel downloading of files in a peer-to-peer network. The Bloom filters encode the pieces of a file that still need to be downloaded. This Bloom filter is sent to peers that contain the file(s). The peers then transmit the requested pieces in parallel.

Byers et al., only uses the Bloom filters for downloading a file and not for describing a location's data content, nor for discovering the location of that file, and not for routing a request for the file in question.

In semantic indexing taught by Tang et al. [Chunqiang Tang, Sandhya Dwarkadas, Zhichen Xu. On scaling latent semantic indexing for large peer-to-peer systems. Proceedings of the 27th annual international conference on Research and development in information retrieval. Pages: 112-121. 2004.], semantic vectors are added to peer-to-peer systems as indexes. Similar to PlanetP, these indexes describe a document and not its data. A compression technique is used that partitions documents into clusters and uses centroids as representative documents.

However, semantic indexing is not good for a large heterogeneous data (document) corpus, and is only best suited for document search/retrieval and not for database retrieval. In addition, semantic indexing does not use a Bloom Filter as underlying indexing scheme.

In Dharmapurikar et al. [Sarang Dharmapurikar, Praveen Krishnamurthy, David E. Taylor. Longest Prefix Matching Using Bloom Filters. Proceedings of the 2003 conference on Applications, technologies, architectures, and protocols for computer communications. Pages: 201-212. 2003.], Bloom filters are applied directly to IP routing tables. This work is mainly focused on IPv4 and IPv6 IP address look up performance and is designed for a single-routing-node, traditional IPv4 and IPv6 longest prefix look up. In this apparatus, the database of IP address prefixes is grouped into sets according to IP address prefix length. Each Bloom filter is programmed with the associated set of prefix.

However, each Bloom filter is not directly applicable to content based routing and is only directly applicable to traditional IP address routing because it is optimized for traditional IPv4 and IPv6 addresses. It only improves the performance of a single-node and cannot be extended for inter-node performance improvements.

Czerwinski et al. [S. Czerwinski, B. Y. Zhao, T. Hodes, A. D. Joseph, and R. Katz. An architecture for a secure service discovery service. In Proc. of MobiCom-99, pages 24-35, N.Y., August 1999.] as part of their architecture for a resource discovery service propose a hierarchical routing scheme for resource discovery amongst multiple nodes. Each node in the hierarchy keeps a list of all resources that it contains, or that one of its children's subtrees contain. When a request reaches a node, it checks its lists of resources. If it can satisfy the request from its own resources then it does so directly or, if one of its children can satisfy the request, it forwards the request to that child. Otherwise, the request is forwarded up the hierarchy tree. If the request reaches the top of the tree without being satisfied, then it is denied.

Czerwinski's routing scheme employs a directed acyclic tree graph (DAT). A DAT is known to have the following detrimental properties. If any node or link in the graph is removed, then the connection to all nodes in the subtree is also removed. In addition, Czerwinski indexes objects down to the resource level, where a resource is defined as a file or service.

Czerwinski's indexes are lists of resources. This is not scalable to large numbers of resources because the lists grow linearly with the number of resources and eventually overflow the node's memory or storage capabilities. Therefore the memory requirements for a node are not discrete.

Czerwinski's scheme is designed to return only the nearest copy of the requested resource. It depends on resource replication to avoid every request from turning into a broadcast message. The scheme cannot be upgraded to return the full list of all resources throughout the system that match the request without turning every request into a broadcast message.

Rhea and Kubiatowicz [Sean C. Rhea and John Kubiatowicz. Probabilistic location and routing. In Proceedings of INFOCOM 2002.] in the OceanStore project [J. Kubiatowicz, D. Bindel, P. Eaton, Y. Chen, D. Geels, R. Gummadi, S. Rhea, W. Weimer, C. Wells, H. Weatherspoon, and B. Zhao. OceanStore: An architecture for global-scale persistent storage. ACM SIGPLAN Notices, 35(11):190-201, November 2000.] expand on the work of Czerwinski. An array Bloom filters, called attenuated Bloom filters, take the place of the resource lists in Czerwinski. Furthermore, there is a Bloom filter for each outgoing edge and for each distance d up to some maximum value, so that the d^{th} Bloom filter in the array keeps track of those resources reachable along that edge via d hops. If the resource is within d hops, then the shortest path to that resource is found. As with Czerwinski above, Rhea and Kubiatowicz do not return the full list of all resources throughout the system that match the request. They have worse performance than Czerwinski. They only return the nearest copy of the requested resource within d hops because they only keep track of resources up to d hops away.

Hsiao [P. Hsiao. Geographical region summary service for geographical routing. Mobile Computing and Communications Review, 5(4)25-39, October 2001] describes a geographic routing system for mobile computers. A hierarchical tree network is created for routing. The entire geographic space is recursively subdivided into four squares. For each square region, one of the nodes in the system that lies within that square is assigned to be the owner of that region. Each square in turn is recursively subdivided into four squares and an owner assigned until a square region is reached that contains only its one owner node. Each owner node contains a Bloom filter representing the list of mobile hosts reachable through itself or through its three siblings at each level. Using these filters, a node finds the level corresponding to the smallest geographic region that contains it and the destination, and then forwards a message to the owner of the square region corresponding to the sibling in which the destination node currently resides. The same occurs at each level of the hierarchy, recursing down the hierarchy until the destination node is reached. However, it is only directly applicable to unicast mobile IP address routing because it requires that the single specific destination computer node address be defined as part of the message. Only a single path (one-to-one routing) from a source to a single destination is created.

In addition, it is not directly applicable to general content based routing because the destination is defined by a computer address. This computer address does not contain any information regarding the information stored at that host.

Therefore, it would be advantageous to have appropriate bit vector sizes in a content routing network to reduce the required memory and control information transmission overhead.

### SUMMARY OF THE INVENTION

The invention achieves the goal of reducing the memory and control information transmission overheads in a content routing network by:
1) using a combination of a compression technique different and parameter variations on the summary bit vectors that allow for up to 30% reduction in the bit vector size;
2) using different summary bit vectors sizes throughout the system, instead of the single size that is used in the current state-of-the-art, to reduce the amount of internal control traffic and preventing control overhead congestion during initialization or during periods of high activity.

One embodiment of the invention comprises a method in a content routing network for reducing memory and control information transmission overheads, comprising the step of compressing a summary bit vector of a Bloom filter used in the content routing network. The summary bit vector is compressed using a technique which allows for direct and in-place manipulation of individual bits in the vector, and does not allow for direct and in-place manipulation of individual bits in the vector.

One preferred embodiment of the invention further comprises the steps of uncompressing the compressed summary bit vector; dividing the uncompressed summary bit vector into a first half and a second half; and ORing the first half and second half to reduce a size of the summary bit vector.

One preferred embodiment of the invention further comprises the step of determining a number of independent hash functions and a size of the summary bit vector from a predetermined transmission size and a number of sets to be represented by the Bloom filter. The number of independent hash functions and the size of the summary bit vector are determined to minimize false positive rate.

One preferred embodiment of the invention further comprises the steps of choosing a first size for a data source summary bit vector and choosing a second size for a network summary bit vector. The first size and the second size are chosen such that the second size is smaller than the first size. The first size is chosen to minimize a false positive rate. The second size is chosen to reduce (((0.00001 x−0.0004) x+0.0424) x−3.1857) x+101.75, wherein x is a particular false-positive rate. The second size is chosen through reducing the first size by half.

One preferred embodiment of the invention further comprises the step of assigning a plurality of subsets of bits of the summary bit vector to a corresponding plurality of hash functions.

One preferred embodiment of the invention further comprises the steps of transmitting a renew message from a first node to a second node to cause the second node to set bits of the summary bit vector to allow queries to be transported; sending from the second node a request for a changed bit vector to the first node; selecting one from a plurality of representations to transmit the changed bit vector from the first node, the plurality of representations comprising: a list of ones in a new bit vector; a list of zeroes in the new bit vector; and the new bit vector.

One preferred embodiment of the invention comprises a machine readable medium containing instruction data which, when executed on a data processing system, causes the system to perform a method in a content routing network to reduce memory and control information transmission overhead, the method comprising the steps of choosing a first size for a data source summary bit vector of a Bloom filter; and choosing a second size for a network summary bit vector; wherein the first size and the second size are chosen such that the second size is smaller than the first size. The first size is chosen to minimize a false positive rate; and the second size is chosen to reduce (((0.00001 x−0.0004) x+0.0424) x−3.1857) x+101.75, wherein x is a predetermined false-positive rate. The second size is chosen through repeatedly reducing the first size by half; and generating the network summary bit vector comprises the steps of dividing the data source summary bit vector into a first half and a second half; and ORing the first half and second half.

One preferred embodiment of the invention further comprises the steps of determining a number of independent hash functions and a size of the summary bit vector from a predetermined transmission size and a number of sets to be represented by the Bloom filter; and compressing the network summary bit vector; wherein the number of independent hash functions and the size of the summary bit vector are determined to minimize false positive rate.

One preferred embodiment of the invention further comprises the steps of transmitting a renew message from a first node to a second node to cause the second node to set bits of the summary bit vector to allow queries to be transported; sending from the second node a request for a changed bit vector to the first node; selecting one from a plurality of representations to transmit the changed bit vector from the first node, the plurality of representation comprising a list of ones in a new bit vector; a list of zeroes in the new bit vector; and the new bit vector.

One preferred embodiment of the invention comprises a content routing network comprising means for transmitting a renew message from a first node to a second node to cause the second node to set bits of a summary bit vector to allow queries to be transported; means for sending from the second node a request for a changed bit vector to the first node; means for selecting one from a plurality of representations to transmit the changed bit vector from the first node, the plurality of representation comprising a list of ones in a new summary bit vector of a Bloom filter; a list of zeroes in the new summary bit vector; and the new summary bit vector.

One preferred embodiment of the invention further comprises means for choosing a first size for a data source summary bit vector of a Bloom filter; and means for choosing a second size for a new summary bit vector; wherein the first size and the second size are chosen such that the second size is smaller than the first size. The first size is chosen to minimize a false positive rate; the second size is chosen through repeatedly reducing the first size by half; and content routing network further comprises means for generating the new summary bit vector through dividing the data source summary bit vector into a first half and a second half and ORing the first half and second half.

One preferred embodiment of the invention further comprises means for determining a number of independent hash functions and a size of the data source summary bit vector from a predetermined transmission size and a number of sets to be represented by the Bloom filter; and means for compressing the data source summary bit vector to generate the new summary bit vector; wherein the number of independent hash functions and the size of the summary bit vector are determined to minimize false positive rate.

### BRIEF DESCRIPTION OF THE DRAWINGS

FIG. 1 is a flow diagram illustrating essential parts of a content routing network system for reducing memory and control information overheads according to one embodiment of the invention;

FIG. 2 is a flow diagram illustrating a method of reducing memory and control information overheads according to the invention;

FIG. 3A is a flow diagram illustrating a method in a content routing network to reduce memory and control information transmission overhead according to the invention;

FIG. 3B is a graph that illustrates the relationship of system-wide computation time and false positive rate;

FIG. 4 is a flow diagram illustrating a method of reducing memory and control information overhead according to the invention;

FIG. 5 is a flow diagram illustrating a method of forwarding a message with reduced memory and control information overhead according to the invention;

FIG. 6 is a flow diagram illustrating a method of reducing memory and control information overhead according to the invention; and

FIG. 7 is a flow diagram illustrating a method of reducing memory and control information overhead according to the invention.

### DETAILED DESCRIPTION OF THE INVENTION

Terms

| | |
|---|---|
| Characteristic | Represented as a string of arbitrary length. The string is |
| | not limited to alphanumeric characters and can be |
| | composed of any binary value. A characteristic is |
| | essentially an identifier that represents a distinct group. |
| | Assigning a characteristic to a node is equivalent to |
| | assigning that node membership in the group identified |
| | by the characteristic. |
| QP | Query Processor |
| DQR | Designated Query Router |
| DSM | Data Source Manager |

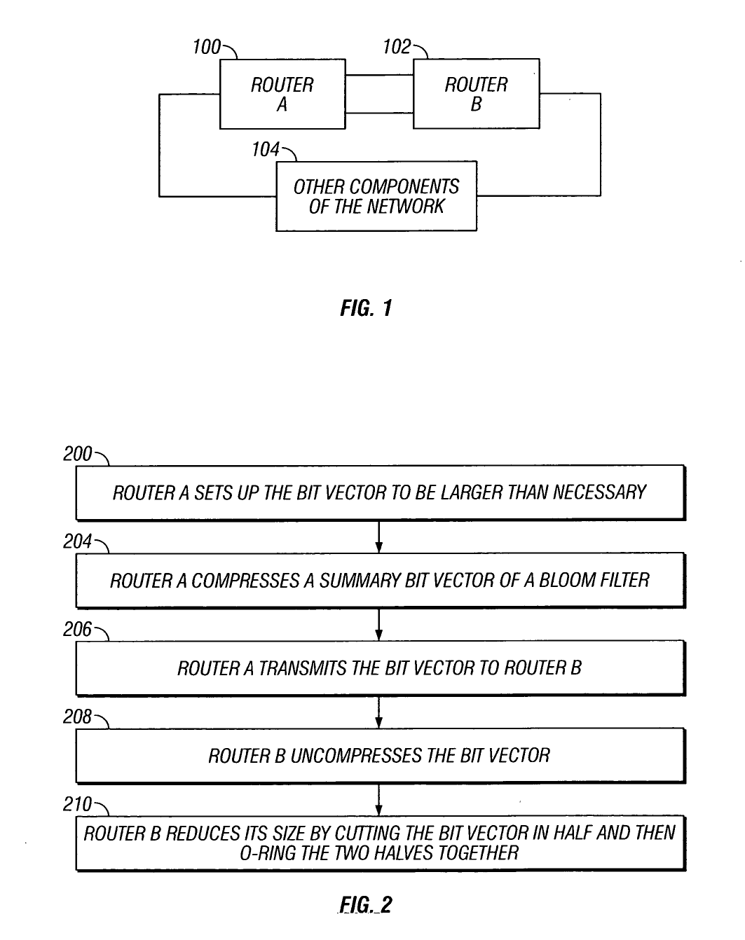

FIG. 1 is a flow diagram illustrating essential parts of a content routing network system for reducing memory and control information overhead according to the invention. The essential parts of a content routing system for reducing memory and control information overhead comprises at least two routers, i.e. router A 100 and router B 102.

Router A 100 performs various functions. For example, router A may receive a message from a user. Router A 100 may compress a summary bit vector of a Bloom filter and maintain a list of all original data source summary bit vectors.

Router B 102 communicates with router A 100 in a content routing network and responds to a variety of queries from router A 100. Details are provided below.

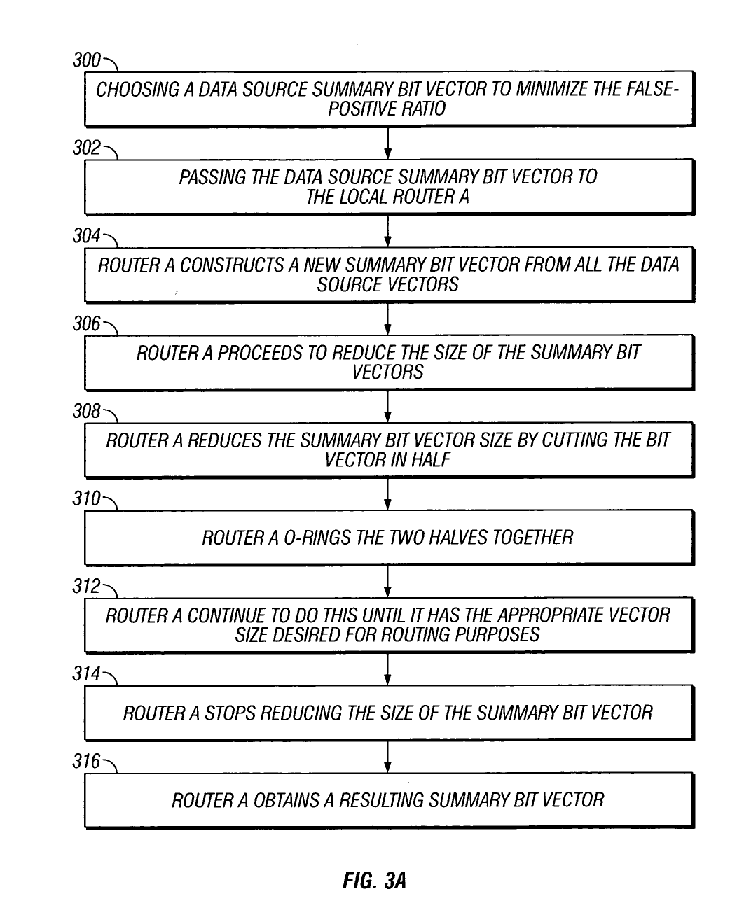

FIG. 2 is a flow diagram illustrating a method of reducing memory and control information overheads according to the invention. A compression technique that does not allow for direct manipulation of individual bits is performed on two routers.

Router A sets up the bit vector to be larger than necessary 200. In this way, router A compresses well when the size of the vector is a factor of two.

Router A compresses a summary bit vector of a Bloom filter 204. Then router A transmits the bit vector to router B 206.

Router B uncompresses the bit vector 108 and reduces its size by cutting the bit vector in half and then ORing the two halves together 210.

Router B continues to do this 212 until Router B has the appropriate vector size desired or the appropriate ratio of false positives is reached for routing purposes 114.

A Bloom filter [Bloom, B. H., “Space/time trade-offs in hash coding with allowable errors,” Comm. of the ACM, 13 (July 1970), pp. 422-426.] is a space efficient randomized data structure for representing sets in order to support membership queries. An m-bit array represents the set S={s₁, s₂, . . . , sₘ} and k as independent hash functions h₁, h₂, . . . , hₖ, such that for 1≦i≦k, hᵢ:x [symbol] {1, 2, . . . , m}, for xεS. The m-bit array is initialized to all 0's and upon the insertion of an element x, hᵢ(x) is set to 1 for 1≦i≦k. To check whether x is in S, check whether hᵢ(x)=1 for 1≦i≦k.

A Bloom filter can yield a false positive, where it suggests that an element x is in S even if it is not. The probability of having a particular bit not set is

$$p = {( 1 - \frac{1}{m} )}^{k n} \approx {ⅇ}^{- \frac{k n}{m}}$$

and, therefore, the probability of a false positive is f=(1−p)^{k} In this example, the minimum false positive rate is

$$f = {( \frac{1}{2} )}^{\frac{m}{n} ln 2} \approx {( 0.6185 )}^{\frac{m}{n}} .$$

Many applications using Bloom filters may need to pass the Bloom filter as a message, and the transmission size Z(Z≦m) can become a limiting factor. If every bit has the same probability, the Bloom filter cannot be compressed (Z=m). In [M. Mitzenmacher. Compressed bloom filters. In Proceedings of the 20th ACM SIGACT-SIGOPS Symposium on Principles of Distributed Computing, pages 144-150, August 2001.], Mitzenmacher proposes, however, if k is choosen such that p, the probability of a bit not being set is not ½, the Bloom filter can be compressed before sending it out, thus reducing the transmission size Z. The lower bound of Z is m×H(p, 1−p), where H(p, 1−p)=−p log₂ p−(1−p) log₂ (1−p) is the entropy of the distribution {p, 1−p}.

In the original setting, m and n are fixed and the value of k is found to minimize f. An additional parameter z stands for the size of the compressed filter. Assuming the optimal compression is achieved, thus z=H(p)m.

Expressing k in terms of m, n and p, then

$$k = - \frac{m}{n} ln p .$$

Hence

$$f = exp ( \frac{- ln p ln ( 1 - p )}{( - {log}_{2} e ) ( p ln p + ( 1 - p ) ln ( 1 - p ) )} ( \frac{z}{n} ) ) .$$

This gives us a minimum false positive rate of

$$f = {ⅇ}^{- \frac{z}{n} ln 2} = {( 0.5 )}^{\frac{z}{n}} < {( 0.6185 )}^{\frac{z}{n}} ,$$

which is a significant improvement over the uncompressed Bloom filter case.

If the goal of optimizing the final compressed size z is to be achieved while keeping the same false positive rate as in the uncompressed Bloom filter case. The false positive rate in the compressed case is

$${( 0.5 )}^{\frac{m}{n} ln 2} .$$

Thus, the optimal compressed size that gives the same false positive rate is z=mln2, saving roughly 30% space.

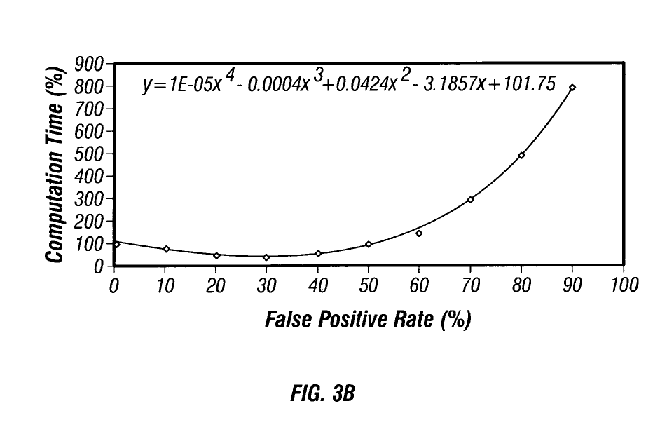

FIG. 3 is a flow diagram illustrating a method in a content routing network to reduce memory and control information transmission overhead according to the invention.

A compression technique according to one embodiment of the invention is used to compress the summary bit vector size to reduce the false-positive ratio so that few unnecessary data sources need to be accessed. This allows for a reduction in the load imposed on the data sources per query so that only the necessary data sources need to be accessed.

However, low false positive ratios typically result in bit vector sizes that are not optimal for routing purposes. A smaller bit vector size is better, even if it means a larger false-positive ratio. Larger summary bit vectors are used at the leaf routing nodes to represent individual data sources. These data source summary bit vectors are configured to emphasize a small false-positive error rate.

Smaller summary bit vectors are used for routing purposes to represent networks. These network summary bit vectors are configured to emphasize a small memory footprint and, as a result, a smaller memory and transmission control overhead.

A method in a content routing network to reduce memory and control information transmission overhead according to the invention comprising the step of choosing a data source summary bit vector to minimize the false-positive ratio 300. The data source false positive ratio is D and the vector size is a power of two. The method further includes the step of passing the data source summary bit vector to the local router A 302.

Router A maintains a list of all of the original data source summary bit vectors. Router A constructs a new summary bit vector from all of the data source vectors 304.

Router A proceeds to reduce the size of the summary bit vector 306 so that it is appropriate for routing purposes.

Router A reduces the summary bit vector size by cutting the bit vector in half 308. Router A ORs the two halves together 310.

Router A continues to do this until it has the appropriate vector size desired for routing purposes 312.

Router A stops reducing the size of the summary bit vector 314 when it is as close as possible to the minimum of the results from the equation, y=1E−05x4−0.0004x3+0.0424x2−3.1857x+101.75, where y is the expected aggregate system-wide computation time required for a particular false-positive ratio x. The aggregate system-wide computation time would include initialization time, update traffic time, and query session creation time. The relationship of system-wide computation time and false positive rate is shown in FIG. 3B.

Router A obtains a resulting summary bit vector 316. The resulting bit vector size is used for routing and placed into the routing table.

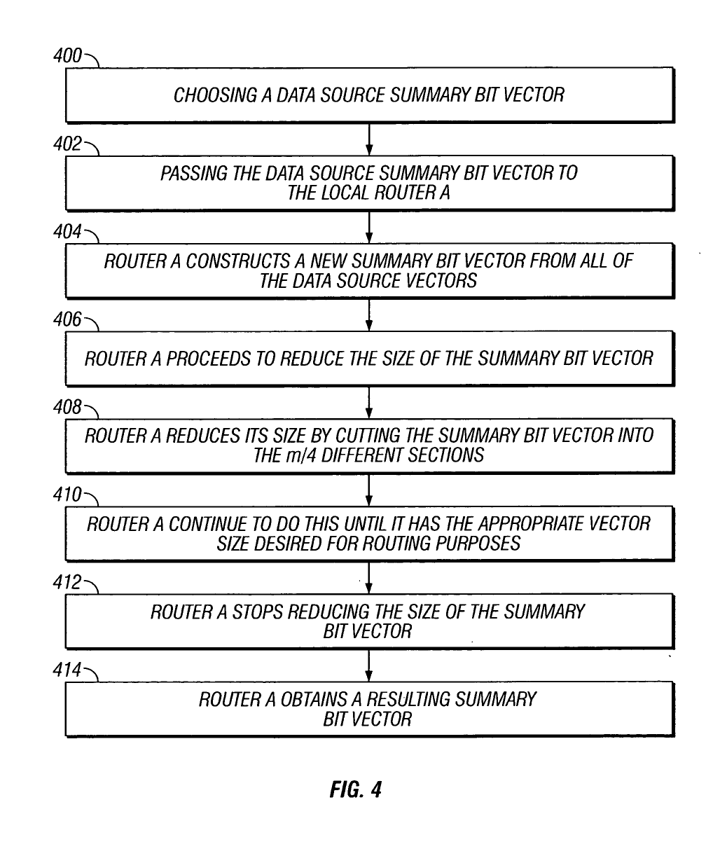

FIG. 4 is a flow diagram illustrating a method of reducing memory and control information overhead according to the invention. A method of reducing memory and control information overhead according to the invention comprises a compression technique that configures the Bloom filters differently such that the summary vector size is divisible by four.

The method according to one embodiment of the invention starts from choosing a data source summary bit vector 400 to minimize the false-positive ratio.

Instead of having one array of size m shared by all of the hash functions, each hash function has a range of m=k consecutive bit locations disjoint from all others. The total number of bits is still m, but the bits are divided equally among the k hash functions. In this case, the probability that a specific bit is 0 is

$${( 1 - \frac{k}{m} )}^{n} \approx {ⅇ}^{- k n / m}$$

Note that the performance is the same as the original scheme. However, because

$${( 1 - \frac{k}{m} )}^{n} \leq {( 1 - \frac{1}{m} )}^{k n}$$

the probability of a false positive is slightly higher with this division.

The total bit vector size is m and the data source false positive ratio is D. The summary vector size is divisible by four. Referring back to the equation above, the bits in the vector are divided equally among the k hash functions and each hash function has a range of m/4 consecutive bit locations disjoint from all others.

The method continues within a step of passing the summary vector to Router A 402.

Router A maintains a list of all original data source summary bit vectors. Router A constructs a new summary bit vector from all of the data source vectors 404.

Router A proceeds to reduce the size of the summary bit vector 406 so that it is appropriate for routing purposes.

Because the vector is a power of four, router A reduces its size by cutting the summary bit vector into the m/4 different sections 408. In this step, each section pertains to a different hash function. The first m/4 section is used for routing and placed into the routing table. The false positive ratio for routing is R.

Router A continues to do this until it has the appropriate vector size desired for routing purposes 410. Router A stops reducing the size of the summary bit vector 412 and obtains a resulting summary bit vector 414.

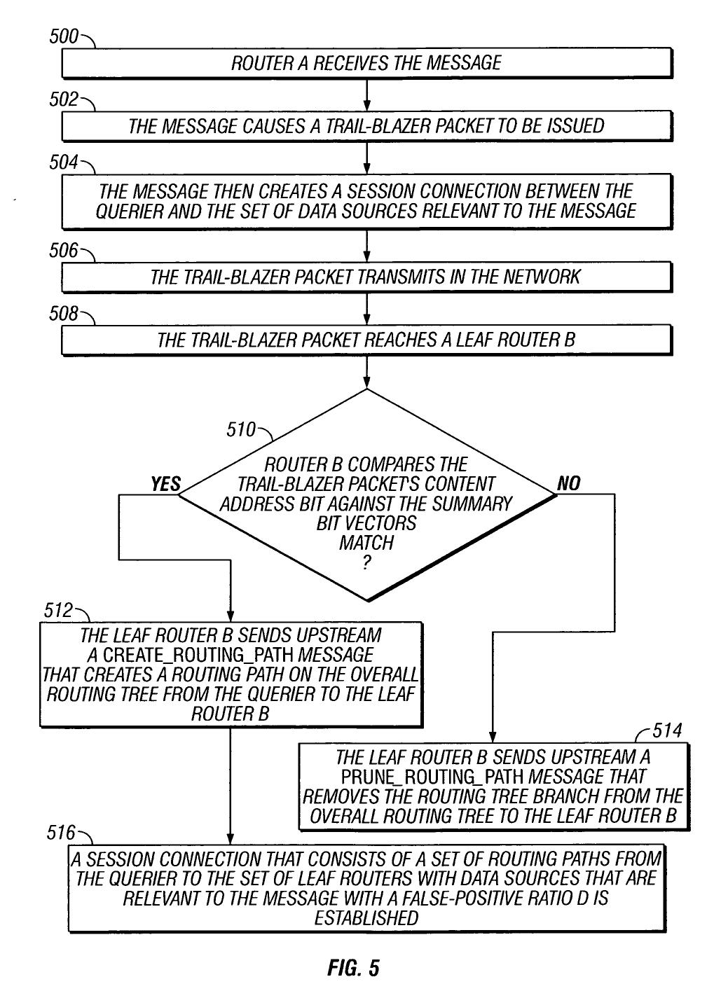

FIG. 5 is a flow diagram illustrating a method of forwarding a message with reduced memory and control information overhead according to the invention. When a user sends a message, router A receives the message 500. The message causes a trail-blazer packet to be issued 502. The message then creates a session connection between the querier and the set of data sources relevant to the message 504.

Because of the smaller bit vectors and the higher false-positive ratio R used for routing, a trail-blazer packet initially is sent to more routers than strictly necessary.

The trail-blazer packet transmits in the network 506 and reaches a leaf router B 508. Router B compares the trail-blazer packet's content address bits against the summary bit vectors for all of the data sources that it controls 510.

If at least one data source is a match, then the leaf router B sends upstream a CREATE_ROUTING_PATH message that creates a routing path on the overall routing tree from the querier to the leaf router B 512.

If none of the data sources are a match, then the leaf router B sends upstream a PRUNE_ROUTING_PATH message that removes the routing tree branch from the overall routing tree to the leaf router B 514.

As a result, a session connection that consists of a set of routing paths from the querier to the set of leaf routers with data sources that are relevant to the message with a false-positive ratio D is established 516.

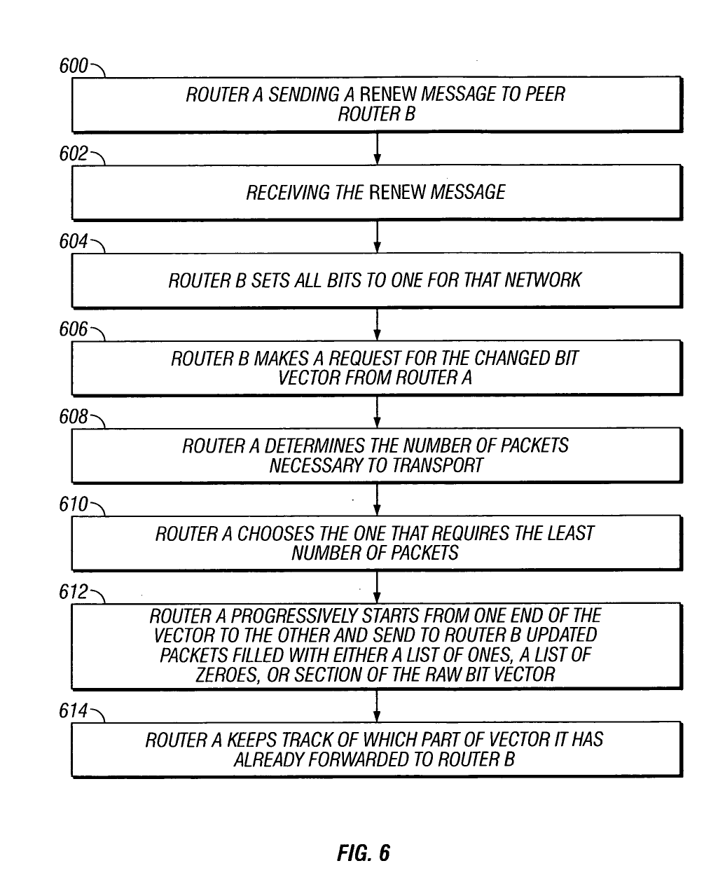

FIG. 6 is a flow diagram illustrating a method of reducing memory and control information overhead according to the invention.

This embodiment of the invention assumes that router A propagates a summary bit vector V to its neighbor peer router B and that a significantly large number of new data items of being indexed resulting in a large number of bits that need to be set to one.

When a summary bit vector is be propagated, router A sends a RENEW message to peer router B 600. Upon receiving the RENEW message 602, router B sets all bits to one for that network 604. In this manner, queries can continue to be transported to that network even though a large update is in progress. Router B makes a request for the changed bit vector from router A 606 using a pull model instead of a push model, where router A simply propagates the new bit vector to router B.

Router A determines the number of packets necessary to transport 608:
1) a list of ones in the bit vector, where the summary bit vector mostly consists of zeroes because a large data source has been removed;
2) the list of zeroes in the bit vector mostly consists of ones because a large data source has been added;
3) the raw bit vector itself because the raw bit vector itself indicates that the bit vector is a mixture of equivalent numbers of ones and zeroes. In this case, the bit vector itself is sent.

As a result, router A chooses the one that requires the least number of packets 610.

Router A progressively starts from one end of the vector to the other and send to router B updated packets filled with either a list of ones, a list of zeroes, or sections of the raw bit vector 612. Each successive packet is spaced out properly to minimize any disruption to the underlying network. Consequently, the transportation of the full bit vector information may take a lengthy period of time.

Because of the length of time required for the complete bit vector information to be transported, the new bits must be merged with the full update that is in progress, when new bit updates are received for that same bit vector.

Router A keeps track of which part of vector it has already forwarded to router B.
Let V_{A}={b₁, b₂, . . . , bₖ, . . . , bₘ₋₁, bₘ,} represent the summary bit vector at router A where:
   i. m represents the number of bits
   ii. h represents the point in the vector dividing the delivered part and the undelivered part. So, for h≦i≦m, the bit bᵢ is delivered and for h≦j≦m, the bit bⱼ is undelivered.
      If it gets an update for bᵢ, router A forwards the update to router B in addition to incorporating it into V_{A}. Router B then incorporates the update for bᵢ into its own bit vector V_{B}.
      If it gets an update for bⱼ, router A incorporates the update into V_{A} and not sends an update to router B because router B has not yet received that part of the summary bit vector.

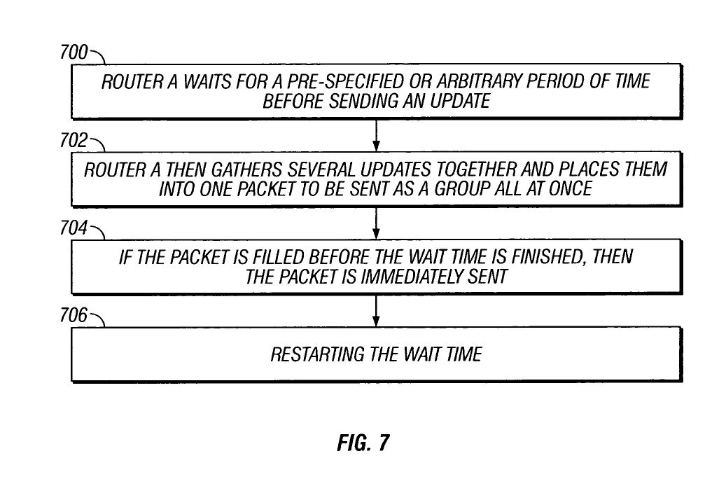

FIG. 7 is a flow diagram illustrating a method of reducing memory and control information overhead according to the invention. A large burst of data source updates occurs but does not require a full bit update, a bust method of update propagation is used.

Router A waits for a pre-specified or arbitrary period of time before sending an update 700. Router A then gathers several updates together and places them into one packet to be sent as a group all at once 702.

If the packet is filled before the wait time is finished, then the packet is immediately sent 704 and the wait time restarted 706.

Although the invention is described herein with reference to the preferred embodiment, one skilled in the art will readily appreciate that other applications may be substituted for those set forth herein without departing from the spirit and scope of the present invention. Accordingly, the invention should only be limited by the claims included below.

1. A method in a content routing network for reducing memory and control information transmission overhead, comprising the step of:
compressing a summary bit vector of a Bloom filter used in the content routing network.

2. The method of claim 1, wherein said summary bit vector is compressed using a technique which allows for direct and in-place manipulation of individual bits in the vector.

3. The method of claim 1, wherein the summary bit vector is compressed using a technique which does not allow for direct and in-place manipulation of individual bits in the vector; and the method further comprises the steps of:
uncompressing the compressed summary bit vector;
dividing the uncompressed summary bit vector into a first half and a second half; and
ORing the first half and second half to reduce a size of the summary bit vector.

4. The method of claim 1, further comprising the step of:
determining a number of independent hash functions and a size of the summary bit vector from a predetermined transmission size and a number of sets to be represented by the Bloom filter.

5. The method of claim 4, wherein the number of independent hash functions and the size of the summary bit vector are determined to minimize false positive rate.

6. The method of claim 1, further comprising the steps of:
choosing a first size for a data source summary bit vector; and
choosing a second size for a network summary bit vector;
wherein the first size and the second size are chosen such that the second size is smaller than the first size.

7. The method of claim 6, wherein the first size is chosen to minimize a false positive rate.

8. The method of claim 7, wherein the second size is chosen to reduce (((0.00001 x−0.0004) x+0.0424) x−3.1857) x+101.75, wherein x is a particular false-positive rate.

9. The method of claim 8, wherein the second size is chosen through reducing the first size by half.

10. The method of claim 1, further comprising the step of:
assigning a plurality of subsets of bits of the summary bit vector to a corresponding plurality of hash functions.

11. The method of claim 1, further comprising the steps of:
transmitting a renew message from a first node to a second node to cause the second node to set bits of the summary bit vector to allow queries to be transported;
sending from the second node a request for a changed bit vector to the first node;
selecting one from a plurality of representations to transmit the changed bit vector from the first node, the plurality of representation comprising:
a list of ones in a new bit vector;
a list of zeroes in the new bit vector; and
the new bit vector.

12. A machine readable medium containing instruction data which, when executed on a data processing system, causes the system to perform a method in a content routing network for reducing memory and control information transmission overhead, the method comprising the steps of:
choosing a first size for a data source summary bit vector of a Bloom filter; and
choosing a second size for a network summary bit vector;
wherein the first size and the second size are chosen such that the second size is smaller than the first size.

13. The medium of claim 12, wherein the first size is chosen to minimize a false positive rate; and the second size is chosen to reduce (((0.00001 x−0.0004) x+0.0424) x−3.1857) x+101.75, wherein x is a predetermined false-positive rate.

14. The medium of claim 13, wherein the second size is chosen through repeatedly reducing the first size by half; and generating the network summary bit vector comprises the steps of:
dividing the data source summary bit vector into a first half and a second half; and
ORing the first half and second half.

15. The medium of claim 12, the method further comprising the steps of:
determining a number of independent hash functions and a size of the summary bit vector from a predetermined transmission size and a number of sets to be represented by the Bloom Filter; and
compressing the network summary bit vector;
wherein the number of independent hash functions and the size of the summary bit vector are determined to minimize false positive rate.

16. The medium of claim 15, wherein the method further comprises the steps of:
transmitting a renew message from a first node to a second node to cause the second node to set bits of the summary bit vector to allow queries to be transported;
sending from the second node a request for a changed bit vector to the first node;
selecting one from a plurality of representations to transmit the changed bit vector from the first node, the plurality of representation comprising:
a list of ones in a new bit vector;
a list of zeroes in the new bit vector; and
the new bit vector.

17. A content routing network, comprising:
means for transmitting a renew message from a first node to a second node to cause the second node to set bits of a summary bit vector to allow queries to be transported;
means for sending from the second node a request for a changed bit vector to the first node;
means for selecting one from a plurality of representations to transmit the changed bit vector from the first node, the plurality of representation comprising:
a list of ones in a new summary bit vector of a Bloom filter;
a list of zeroes in the new summary bit vector; and
the new summary bit vector.

18. The content routing network of claim 17, further comprising:
means for choosing a first size for a data source summary bit vector of a Bloom filter; and
means for choosing a second size for a new summary bit vector;
wherein the first size and the second size are chosen such that the second size is smaller than the first size.

19. The content routing network of claim 18, wherein the first size is chosen to minimize a false positive rate; the second size is chosen through repeatedly reducing the first size by half; and content routing network further comprises:
means for generating the new summary bit vector through dividing the data source summary bit vector into a first half and a second half and ORing the first half and second half.

20. The content routing network of claim 18, further comprising:
means for determining a number of independent hash functions and a size of the data source summary bit vector from a predetermined transmission size and a number of sets to be represented by the Bloom Filter; and
means for compressing the data source summary bit vector to generate the new summary bit vector;
wherein the number of independent hash functions and the size of the summary bit vector are determined to minimize false positive rate.
